(19) United States
(12) Patent Application Publication
(10) Pub. No.: US 2011/0233609 A1
(43) Pub. Date: Sep. 29, 2011

(54) Method for Producing Infrared-Photosensitive Matrix Cells Adhering to an Optically Transparent Substrate by Molecular Adhesion, and Related Sensor

(75) Inventors: Arnaud Cordat, Paris (FR); Herve Sik, Paris (FR); Stéphane Demiguel, Paris (FR)

(73) Assignee: Sagem Defense Securite, Paris (FR)

(21) Appl. No.: 13/130,705

(22) PCT Filed: Nov. 27, 2009
(86) PCT No.: PCT/FR09/52328

§ 371 Date: May 23, 2011

(30) Foreign Application Priority Data
Nov. 27, 2008 (FR) 0858073

(51) Int. Cl. H01L 27/144; H01L 31/18

(52) U.S. Cl. 257/189; 438/65; 257/184; 257/188; 257/E31.067; 257/E27.128

(57) ABSTRACT

The invention relates to a method for producing an infrared radiation sensor, said sensor comprising an infrared photodiode array formed in a first material and a reading circuit formed in a second material, said method comprising the steps of: sticking, through molecular adhesion, a first material side surface onto an optically transparent crystalline material side surface having infrared radiation and a coefficient of thermal expansion similar to that of the second material, give or take 20%; thinning the body of the first material side surface so that the latter is less that 25 μm; producing infrared-sensitive photodiodes onto the thus-thinned first material side surface; depositing contact ball bearings onto the infrared photodiodes; and mounting the reading circuit onto the first material side surface through flip chip technology.

### TECHNICAL FIELD

The present invention relates to a method for producing infrared-photosensitive matrix cells and the resulting component.

### PRIOR ART

Some III-V or II-VI semiconducting materials, and in particular indium antimonide (InSb), have capacities for photodetection of the 3 to 5 μm infrared wavelength band, which is highly advantageous for the development of infrared imaging sensors.

At present, these sensors comprise an InSb wafer on which the photosensitive matrix cells have been produced, and a wafer of silicon or equivalent materials serving as a basis for the CMOS technology, on which the reading circuits are produced.

The production method comprises the following steps:
Creating pixels in the form of a photodiode matrix in an InSb wafer having an initial thickness of about 650 μm and a diameter of about 75 mm (3 inches);
depositing beads of pure indium so that each photodiode is connected to one and only one indium bead; and, in parallel;
creating the read-out circuit on a silicon wafer, the read-out circuit comprising contact zones in a matrix mirroring the photodiode matrix; and
depositing pure indium beads;
   then, the two wafers having been processed, they are cut out respectively into photodiode matrices and read-out circuits, which are joined together by the flip chip technique. The flip chip joining technique is well known to a person skilled in the art and is therefore not described in detail here.

To ensure the stiffness and mechanical solidity of the assembly, and also its chemical protection, adhesive is injected between the photodiode matrix and the read-out circuit, which are joined together with a separating gap of about 10 μm.

The body of the InSb wafer is then thinned to about 10 μm by mechanical and/or chemical polishing or any other technique.

This thickness allows good penetration of the photons to the photodiode level without loss by recombination, while limiting the cross-talk effects due to transverse diffusion of the electrons/holes.

After this thinning, an antireflecting coating is added on the InSb layer.

Owing to the small width of the InSb band gap, the thermal generation of electron/hole carriers prevents the InSb sensor from performing its photodetection function above a certain operating temperature. Thus the sensor must be cooled down to a cryogenic temperature lower than 80K.

Due to the difference in expansion coefficient between silicon and InSb, mechanical stresses are applied to the InSb matrix during the transition from ambient temperature to cryogenic temperature, and, since it is very thin, crystalline cracks appear in the matrix, which may even break.

It has been found that if the thickness of the InSb matrix were maintained at 650 μm, it would become strong enough to withstand breakage due to the mechanical stresses generated by cooling.

Thus, to solve this problem of brittleness, it has been proposed to modify the doping of the InSb wafer to make it transparent to infrared radiation because of the MOSS-BURSTEIN effect.

However, this requires growing an InSb layer by epitaxy, said layer being less doped to produce the photodiodes therein.

Finally, the InSb layer must nevertheless be thinned within a range of 50 to 200 μm to take account of the effects of absorption by remaining free carriers. With these thicknesses, breakage of the InSb layer continues to occur, but with a lower probability than for components obtained by the conventional method.

In the case of a high InSb thickness, the stresses generated by cooling can be transferred to the indium beads, as this occurs in the case of infrared photodiode matrices based on mercury-indium-tellurium (HgCdTe) material, as described in patent FR 2 810 453.

In this document, the HgCdTe epitaxy support wafer is thinned, or even eliminated. However, the thermomechanical stresses liable to cause fracture are compensated for at the read-out circuit. The silicon support wafer is replaced by a material such as gallium arsenide GaAs, germanium, or sapphire, whose thermal expansion is similar to that of HgCdTe. The ability of this assembly to withstand variations in temperature is ensured by a method of bonding by molecular adhesion.

Another solution for circumventing the problems of fracture on thin InSb layers consists in bonding an optically transparent support as described in patent EP 0 485 115. The thermomechanical stresses are indeed minimized because the production method described makes it possible to obtain a matrix comprising islands of photodiodes physically separated and interconnected via a metallization grid. However, this production method is still very complex and the resulting component suffers from a decrease in quantum yield because a fill ratio is reduced by the metallization grid.

Moreover, this method does not solve the thermomechanical stresses in the conventional case of a matrix of photodiodes that are present on the same InSb wafer.

### SUMMARY OF THE INVENTION

It would therefore be particularly advantageous to have a method for producing infrared image sensors that is inexpensive and in which the resulting components have good resistance to the mechanical stresses generated by cooling to low temperature.

Thus, an object of the invention is a method for producing an infrared radiation sensor comprising an infrared photodiode array formed from a first material and a read-out circuit formed from a second material. The method comprises the steps of:
bonding, by molecular adhesion, a wafer based on a first material to a wafer of material optically transparent to infrared radiation and having a thermal expansion coefficient similar to that of the second material to within 20%;
thinning the body of the matrix based on first material so that its thickness is lower than 25 μm;
producing infrared-sensitive photodiodes on the wafer based on the first material thus thinned;
depositing contact beads at the infrared photodiodes;
mounting the read-out circuit formed from the second material on the wafer based on first material by the flip chip technology.

This method advantageously allows the use of various materials for the transparent material and for the wafer for producing the photodiodes having the requisite characteristics, wherein the selection may be performed according to other criteria such as cost, ease of implementation, etc.

The optically transparent material is silicon in the case of present read-out circuits, but may be extended to other materials, especially if the technologies of these circuits were to evolve toward other supports, such as those made of GaAs or of indium phosphide (InP).

The infrared photodiodes may be formed from InSb or from a superarray-sensing layer of gallium antimonide (GaSb)/indium arsenide (InAs).

This method may also comprise a prior step of epitaxial growth of an antimony-based layer suitable for forming the infrared photodiodes, said growth being carried out on an epitaxial substrate based on InSb or GaSb, and the thickness of the epitaxial layer being such that the body thinning step removes all of the epitaxial substrate.

A further object of the invention is the sensor resulting from the above method as claimed in claim 8.

### BRIEF DESCRIPTION OF THE DRAWINGS

The invention will be better understood from a reading of the description that follows, provided exclusively as an example, with reference to the appended figures in which:

FIGS. 1A to 1F are schematic views of a method according to an embodiment of the invention; and

FIGS. 2A and 2B are schematic views of an alternative of the method in FIG. 1.

### WAYS OF IMPLEMENTING THE INVENTION

In the figures and the description, the same reference number is used to designate an identical or similar element.

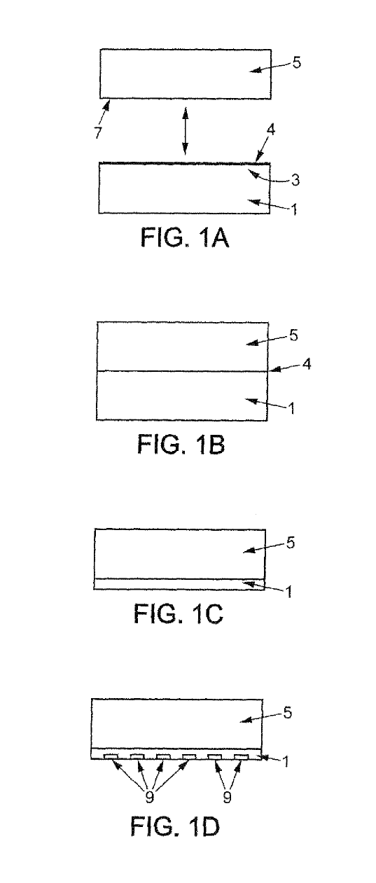

With reference to FIG. 1A, an InSb wafer 1 has its upper surface 3 polished so as to obtain a perfectly planar and smooth surface covered with a thin layer of silicon dioxide 4.

In parallel, a silicon wafer 5 is also polished so that its lower surface 7 is perfectly planar and smooth.

The surfaces 3 and 7 are then placed in contact via the atoms of silicon dioxide, FIG. 1B. The quality of the surfaces is then such that the contact occurs at distances lower than a few nanometers. The attractive or Van der Waals forces between the two surfaces are sufficiently strong to cause molecular adhesion. Conventionally, the assembly is then heated to create covalent bonds in order to reinforce the solidity of the adhesion between the two wafers. Depending on the materials used, the heating temperature is between 400 and 1000° C. It should be observed that the heating step may be replaced by special bonding conditions such as vacuum bonding, preliminary surface treatment by plasma, etc.

Once the two wafers have been bonded together, the InSb wafer 1 is thinned to a thickness of 5 to 25 μm by polishing, FIG. 1C, with the silicon wafer 5 serving as a support layer.

Infrared photodiodes 9 are produced from the thinned InSb wafer, FIG. 1D, by conventional microelectronic methods.

Then, still using standard and well known methods, indium beads 11 are deposited at the height of the photodiodes, FIG. 1E, and a silicon technology read-out circuit 13 is soldered according to the flip chip technique, FIG. 1F.

Thus, the infrared radiation sensor comprises a plurality of infrared photodiodes 9 implanted in an active InSb layer 1. A silicon wafer 5 is bonded to a first face of said active layer by molecular adhesion, and on the second face, the photodiodes are in electrical contact with the read-out circuit 13 via the indium beads 11.

It is found that in this structure, the wafer bonded by molecular adhesion to the InSb layer must be infrared-transparent to allow infrared radiation to reach the photodiodes.

In fact, silicon has this property. This is because silicon has a cutoff wavelength of 1.1 μm, enabling it to be transparent in particular to infrared radiation in the MWIR (Middle Wave Infrared) 3-5 μm bands and LWIR (Long Wave Infrared) 8-12 μm bands, and also to those of the SWIR (Short Wave Infrared) 1-2.7 μm bands. Furthermore, it serves to oppose the effects of thermal expansion because the read-out circuit also has a silicon support.

Thus, when the temperature of the component is lowered down to 77K, the silicon, where the InSb is bonded by molecular adhesion, is capable of accompanying the mechanical stresses generated by the silicon of the read-out circuit, while protecting said thin InSb layer, the electrical circuit of the read-out circuit itself, and the electrical connection of the indium beads.

It is reasonable to assume that any material transparent to infrared radiation and having a thermal expansion coefficient similar to that of the silicon of the read-out circuit is suitable for serving as a support layer. “Similar” is intended to mean that the expansion coefficient is similar to within 20% of that of the silicon, so that it does not by itself create mechanical stresses on the thin active InSb layer, the electrical circuit of the read-out circuit itself and the electrical connection of the indium beads. The use of an identical material for the support of the read-out circuit and for the transparent support layer of the photodiodes, that is to say silicon, serves to minimize the mechanical stresses.

It should be noted that if the read-out circuit were to be fitted onto a material different from silicon, like, for example, GaAs, for reasons of switching speed, for example, the material of the transparent layer could also be GaAs, which is transparent to the infrared wavelengths considered.

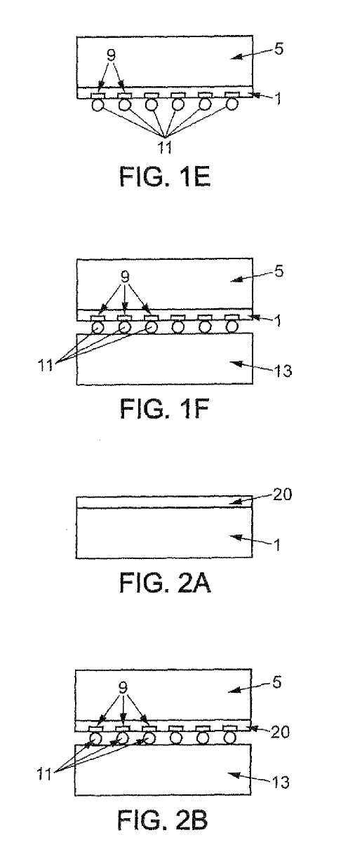

In an alternative method, FIG. 2A, an InSb layer 20 is grown in a preliminary step by epitaxy on the InSb wafer 1 which then serves as the epitaxial support. This epitaxial growth is carried out to form a 5 to 25 μm thick epitaxed InSb layer from which the photodiodes are produced, FIG. 2B.

The advantage of the epitaxed layer is its excellent crystal quality and perfectly controlled intrinsic doping level, thereby providing a very good production yield.

During the body thinning step, it is then possible to completely remove the epitaxial support wafer and only retain the epitaxed layer.

This prior epitaxy step has the advantage of also allowing the use of a wider range of materials.

Thus, since the epitaxial support wafer is completely removed, it can be replaced by other materials allowing the growth of an active layer. Thus, said layer can be based on GaSb, for example.

In order to avoid lattice parameter mismatch dislocations, it is also possible to deposit a buffer layer on the epitaxial support to serve as a growth support for the active epitaxed layer.

Said layer may then be composed of InSb, as well as other antimony-based materials known for their capacity to detect more infrared bands, for example a superarray based on GaSb/InAs.

It is also possible to use materials such as mercury-cadmium-tellurium HgCdTe.

A description has thus been provided of a method for producing infrared sensors and the product resulting from this method which meets the reliability requirements for use at cryogenic temperatures.

1. A method for producing an infrared radiation sensor, said sensor comprising an infrared photodiode array formed from a first material and a read-out circuit formed from a second material, said method comprising the steps of:
bonding, by molecular adhesion, of a wafer based on the first material to a wafer of material optically transparent to infrared radiation and having a thermal expansion coefficient similar to that of the second material to within 20%;
thinning the body of the wafer based on the first material so that its thickness is lower than 25 μm;
producing infrared-sensitive photodiodes on the wafer based on the first material thus thinned;
depositing contact beads at the infrared photodiodes;
mounting the read-out circuit formed from the second material on the wafer based on the first material by the flip chip technology.

2. The method as claimed in claim 1, wherein the transparent material is identical to the second material.

3. The method as claimed in claim 2, wherein the second material is silicon Si.

4. The method as claimed in claim 1, wherein the first material is based on antimony.

5. The method as claimed in claim 4, wherein the infrared photodiodes are formed from indium antimonide or from a superarray-sensing layer of gallium antimonide/indium arsenide.

6. The method as claimed in claim 4, wherein it comprises the prior step of epitaxial growth of an antimony-based layer suitable for forming the infrared photodiodes, said growth being carried out on an epitaxial substrate based on indium antimonide or gallium antimonide, and the thickness of the epitaxial layer being such that the body thinning step removes all of the epitaxial substrate.

7. The method as claimed in claim 1, wherein the first material is based on mercury-cadmium-tellurium HgCdTe.

8. An infrared radiation sensor comprising a plurality of infrared photodiodes in an active layer formed from a first material, said active layer having a first face and a second face, and each photodiode being in contact at the second face with a read-out circuit formed from a second material via a conducting connection and receiving the infrared radiation via the first face, characterized in that a wafer of material optically transparent to infrared radiation is bonded by molecular adhesion to said first face, said optically transparent material having a thermal expansion coefficient similar to that of the second material to within 20%.

9. The sensor as claimed in claim 8, wherein the transparent material is identical to the second material.

10. The sensor as claimed in claim 9, wherein the second material is silicon Si.

11. The sensor as claimed in claim 8, wherein the first material is based on antimony.

12. The sensor as claimed in claim 11, wherein the active layer is composed of indium antimonide or of a superarray of gallium antimonide/indium arsenide.

13. The sensor as claimed in claim 8, wherein the active layer is a layer created by epitaxial growth.

14. The sensor as claimed in claim 8, wherein the first material is based on mercury-cadmium-tellurium HgCdTe.
